(19) United States
(12) Patent Application Publication
(10) Pub. No.: US 2010/0140078 A1
(43) Pub. Date: Jun. 10, 2010

(54) METHOD AND APPARATUS FOR FORMING CONTACT LAYERS FOR CONTINUOUS WORKPIECES

(75) Inventors: Mustafa Pinarbasi, Morgan Hill, CA (US); James Freitag, Sunnyvale, CA (US); Jorge Vasquez, San Jose, CA (US); Bulent M. Basol, Manhattan Beach, CA (US)

Correspondence Address: PILLSBURY WINTHROP SHAW PITTMAN LLP, P.O. BOX 10500, MCLEAN, VA, 22102, US

(73) Assignee: SoloPower, Inc., San Jose, CA (US)

(21) Appl. No.: 12/632,484

(22) Filed: Dec. 7, 2009

Related U.S. Application Data
(60) Provisional application No. 61/200,961, filed on Dec. 5, 2008.

(51) Int. Cl. C23C 14/34; C23C 14/56

(52) U.S. Cl. 204/192.1; 204/298.24

(57) ABSTRACT

The present invention provides a roll to roll system and a method to sputter deposit various conductive films on a back surface and a front surface of a continuous substrate to form protected base structures for Group IBIIIAVIA thin film solar cells. In one embodiment of the invention, a back protection film is sputter deposited onto the entire back side of the substrate in a first deposition station without transferring heat from the substrate. Next, a first front film is sputter deposited in a second deposition station to partially cover the front side of the substrate while heat is transferred from substrate by a cooling surface of a cooling mechanism in the second deposition station. The second film does not cover the edges of the substrate to avoid contaminating the cooling surface with the depositing material. Other embodiments are directed to specifics regarding the depositing of these films, adding other films, and a system for depositing the films.

### CLAIM OF PRIORITY

This application claims priority to U.S. Provisional Application Ser. No. 61/200,961 filed Dec. 5, 2008, the contents of which are incorporated herein by reference.

### BACKGROUND

1. Field of the Invention

The inventions relate to deposition methods and, more particularly, to methods for physical vapor deposition of thin films on a flexible surface in a roll-to-roll fashion for manufacturing solar cells.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ , where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which includes a material in the family of Cu(In,Ga,Al)(S,Se,Te)₂, is grown over a contact layer 13 or conductive layer, which is previously deposited on the substrate 11 and which acts as the electrical contact to the device. The absorber film 12 is typically formed by a co-deposition approach or a two-stage approach. In co-deposition approach all components of the absorber film 12 (i.e. Cu, In, Ga and Se) are delivered onto the contact layer of a base heated to a temperature in the range of 400-600° C. These components react under the influence of heat and form the compound. In a two-stage process a precursor layer including Group IB and Group IIIA elements are first deposited on the contact layer during the first stage of the process. In the second stage the precursor film is heated up to temperatures in the range of 400-600° C. and reacted with one of Se and S to form the CIGS(S) type absorber layer. The substrate 11 and the contact layer 13 form a base 20 on which the absorber film 12 is formed. Various conductive layers comprising Mo, Ta, W, Ti, and their alloys and nitrides have been used in the solar cell structure of FIG. 1. If the substrate itself is a properly selected conductive material, it is possible not to use a contact layer 13, since the substrate 11 may then be used as the ohmic contact to the device. After the absorber film 12 is grown, a transparent layer 14 such as a cadmium sulfide (CdS) layer, a transparent conductive oxide (TCO) film such as a zinc oxide (ZnO) layer or a CdS/ZnO stack is formed on the absorber film. Radiation 15 enters the device through the transparent layer 14. Metallic grids (not shown) may also be deposited over the transparent layer 14 to reduce the effective series resistance of the device.

A variety of materials, deposited by a variety of methods such as evaporation, electroplating and sputter deposition, can be used to provide the various layers of the solar cell device shown in FIG. 1. Sputtering and evaporation techniques, which are also known as physical vapor deposition (PVD) techniques, are the preferred methods to deposit contact layers and the TCO portions of transparent layers, although they may be used to deposit the components of the precursor films also. Such layers can be deposited on a continuous flexible substrate using well known roll-to-roll process tools in which the flexible substrate is fed from a supply roll into a process chamber and after receiving deposition, the flexible substrate is taken up from the process chamber and wrapped around a receiving roll. The process chamber can have for example one or more sputtering cathodes to deposit a desired material onto the continuous flexible substrate from the targets mounted on the cathodes.

In general, the process chambers are equipped with a support apparatus to support the continuous flexible substrate during the deposition. FIG. 2A shows a perspective view of an exemplary cylindrical support apparatus 50 or a drum, supporting a continuous flexible substrate 52 or web. The drum 50 is used to control the tension of the flexible substrate and to transfer the heat out of the flexible substrate. The cooling material in the drum can be circulating oil, water, or gas, which cool the surface of the drum supporting the flexible substrate. This way heat is transferred from the flexible substrate, which substrate is heated by the sputtering cathodes. Top surface 54 of the flexible substrate 52 is exposed to the depositing material (depicted as arrows “M”) originating from the target materials mounted on the cathodes. During the process, the flexible substrate 52 is advanced while in contact with a curved surface 56 of the drum 50 which rotates as the flexible substrate moves.

The quality of the deposited film depends upon the physical contact between the flexible substrate and the drum surface, which is preferably a perfectly cylindrical surface. Therefore, cleanliness of the drum surface is important, including on edge areas 58 of the curved surface 56. Any contaminant in the form of unwanted deposits from the sputtering cathode to an edge area can find its way under the flexible substrate and disturb the physical contact between the flexible substrate 52 and the curved surface 56, thereby reducing the heat transfer between the substrate and the drum. In addition, such deposits can cause the flexible substrate to deform non-uniformly, affecting the overall quality of the deposited film.

One method of preventing this unwanted deposition to the edge area 58 is keeping the depositing material away from the edge area 58 by placing area limiting masks between the sputtering cathodes and the surface 54 of the flexible substrate 52. However, although this preventive measure, which is called edge excluded deposition, succeeds in preventing unwanted deposition over the edge area, it causes a deposit free area or strip along the edges of the flexible substrate. FIG. 2B shows a portion 52A of a front surface 60 of the flexible substrate 52 having the edge excluded deposition of the prior art. As can be seen in FIG. 2B, an area 62 adjacent the edges of the flexible substrate is deposit-free and exposed while a deposited layer 64 covers a central region of the flexible substrate. Especially in CIGS absorber layer growth approaches that involve two-stage processing on metallic foil substrates such as flexible stainless steel substrate, any exposed stainless steel surface is reacted and corroded during the second stage of the process when reaction with Se and/or S is carried out at elevated temperature. Such corrosion introduces unwanted contamination and particle formation in reaction chambers where the second stage of the process is carried out.

Therefore, from the foregoing, there is need for a deposition technology that is able to deposit at least some materials over the full surface of the flexible substrates in roll-to-roll systems without causing any of the above explained contamination drawbacks.

### SUMMARY

The present invention provides roll to roll systems and methods to sputter deposit various conductive films on a back surface and a front surface of a continuous substrate to form protected base structures for Group IBIIIAVIA thin film solar cells.

In one embodiment, a back protection film is sputter deposited onto the entire back side of the substrate in a first deposition station without transferring heat from the substrate. Next, a first front film is sputter deposited in a second deposition station to partially cover the front side of the substrate while heat is transferred from substrate by a cooling surface in the second deposition station. The second film does not cover the edges of the substrate to avoid contaminating the cooling surface with the depositing material.

In another aspect, a third film is sputter deposited after the films mentioned in the one embodiment have been deposited, with the third film sputter deposited onto both the first front film and the exposed edges of the substrate in a third deposition station.

In another aspect, a third film is sputter deposited before the second film mentioned in the one embodiment above has been deposited, with the third film sputter deposited onto the entire front side of the substrate, and then the second film, instead of being applied on the front side of the substrate, is applied on the third film.

Still other aspects and embodiments are directed to specifics regarding the depositing of these films, adding other films, and a system for depositing the films.

### BRIEF DESCRIPTION OF THE DRAWINGS

FIG. 1 is a schematic view of a prior art solar cell structure;

FIG. 2A is a perspective view of a prior art roll-to-roll system depositing a conductive material on a surface of a continuous flexible substrate;

FIG. 2B is a schematic view of a portion of the surface of the continuous flexible substrate having a deposited layer formed by an edge excluded deposition technique of the prior art.

FIG. 3A is a schematic view of a roll-to-roll deposition system of an embodiment to deposit conductive materials over a full front and back surface of a continuous flexible substrate;

FIG. 3B is a schematic view of a roll-to-roll deposition system of another embodiment to deposit a conductive material over a full front and back surface of a continuous flexible substrate;

FIG. 3C is a schematic view of a roll-to-roll deposition system of another embodiment to deposit a conductive material over a full front and back surface of a continuous flexible substrate;

FIGS. 4A-4C are schematic side views of the various structures formed using the deposition system shown in FIG. 3A;

FIG. 4D is a schematic view of a portion of the front surface of the continuous flexible substrate having a deposited layer covering the full front surface, which is formed using the deposition systems shown in FIG. 3A;

FIG. 5 is a schematic side view of an alternative structure formed using the system shown in FIG. 3B;

FIG. 6 is a schematic view of another embodiment of a roll-to-roll deposition system;

FIG. 7 is a schematic side view of a structure formed using the deposition system shown in FIG. 6; and

FIG. 8 is a schematic side view of a structure formed using the deposition system shown in FIG. 3C.

### DETAILED DESCRIPTION OF THE PREFERRED EMBODIMENTS

The embodiments described herein provide a roll-to-roll sputter deposition system for depositing thin films on flexible continuous substrates for manufacturing CIGS type solar cells on such substrates. The system may be used to form bases or protected base structures including a flexible substrate and one or more conductive layers formed on the substrate. The conductive layers may be formed over at least one of a back surface and a front surface of the flexible substrate.

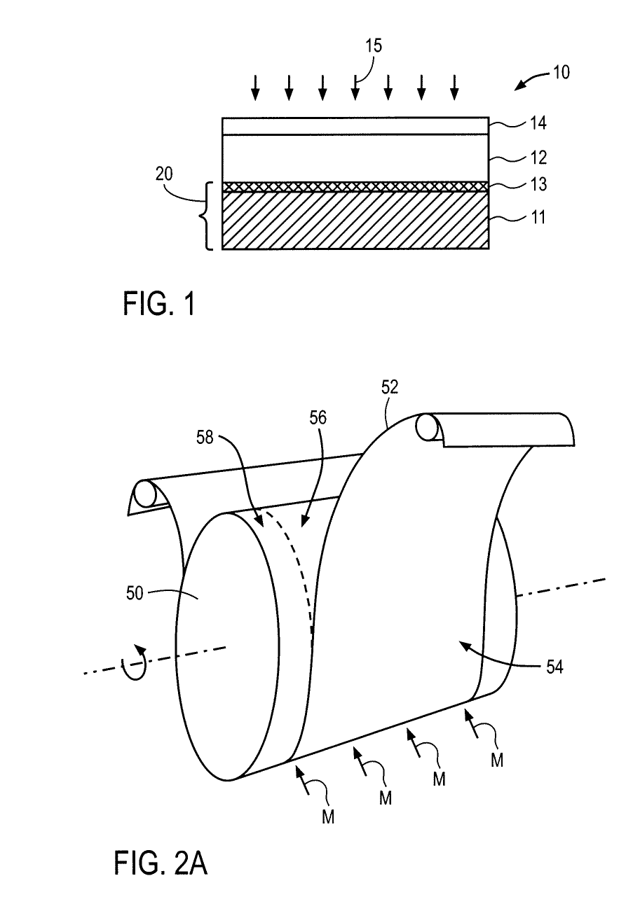

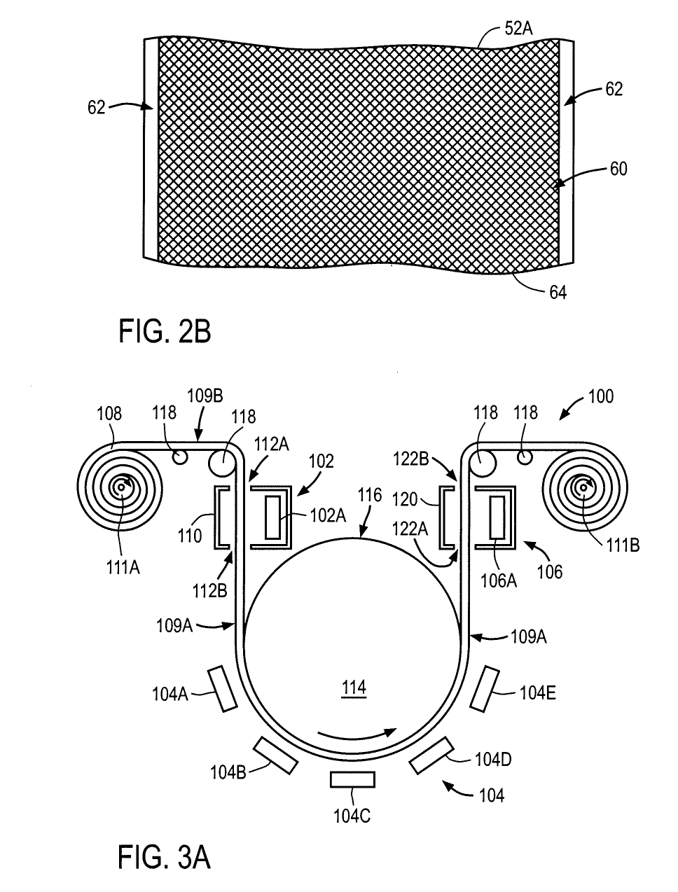

In one embodiment, initially a back conductive layer is formed over a back surface of a continuous substrate by depositing a first conductive material in a first deposition station while the flexible substrate is advanced towards a second deposition station including a support base or drum of the system. The back conductive layer entirely covers the back surface without excluding any back surface portion. Next, a front partial conductive layer is formed by depositing a second conductive material over a front surface of the flexible substrate by depositing the second conductive material in the second deposition station while the flexible substrate is supported by a curved surface of the support base of the system and advanced towards a third deposition station. The support base may be a drum to support the flexible substrate while the front partial conductive layer is formed. In this step, the front partial conductive layer generally covers a central area of the front surface while leaving the edges of the front surface of the flexible substrate exposed thereby avoiding any unwanted material deposition over the curved surface of the drum. In the following step, a front full conductive layer is formed over the front surface, covering the exposed edges of the front surface and the front partial conductive layer formed on the front surface, by depositing a third conductive material in the third deposition station while the flexible substrate is advanced away from the third deposition station. The first, second and third conductive materials may be different conductive materials or the same conductive material. The roll-to-roll system in the embodiments described herein may be used to manufacture bases, such as base 20 shown in FIG. 1, for Group IBIIIAVIA thin film solar cells.

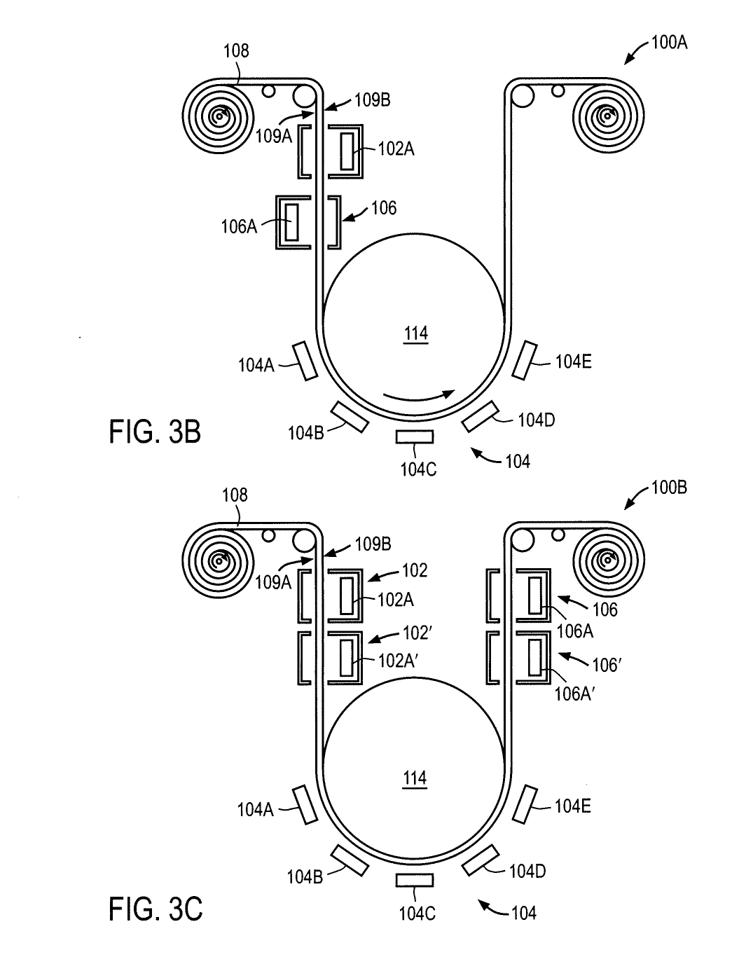

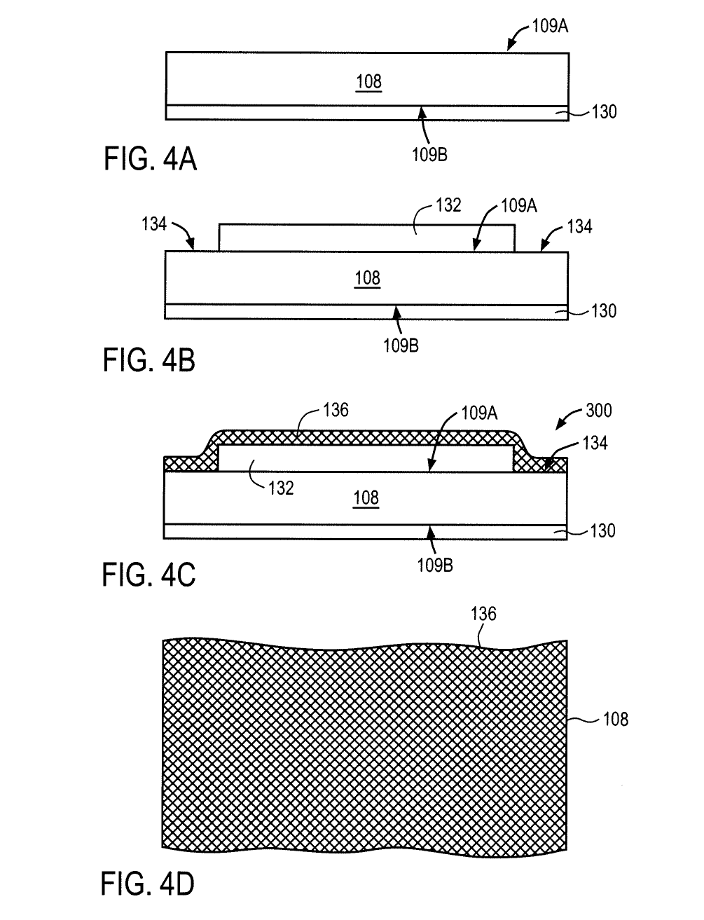

3A shows a roll-to-roll system 100 having a first deposition station 102, a second deposition station 104 (shown as having various units 104A, 104B, 104C, 104D, and 104E) and a third deposition station 106 to deposit conductive material layers over a workpiece 108 with a front surface 109A and a back surface 109B, as the workpiece 108 is advanced through the deposition station 102, 104 and 106 in a process direction. The deposition stations 102, 104 and 106 or the system 100 may be in a chamber or enclosure (not shown). The chamber may or may not be under vacuum. The workpiece may be a continuous conductive flexible substrate such as a stainless steel foil, an aluminum based foil or another metallic foil. The conductive materials to be deposited may include refractory metals such as molybdenum (Mo), tantalum (Ta), tungsten (W), titanium (Ti), their alloys with other metals, their nitrides, Ru, Ir, Os, etc. During the process, the workpiece 108 is advanced from a supply spool 111A into the first deposition station 102, the second deposition station 104, and the third deposition station 106, and received by a receiving spool 111B. A deposition process according to the embodiments herein will now be described in connection to FIG. 3A and FIGS. 4A-4D to form a first protected base structure 300 shown in FIG. 4C. FIGS. 4A-4C show cross sectional views of the deposited layers and the workpiece taken along the width of the workpiece.

The first deposition station includes an enclosure or shield 110 in which a deposition unit 102A is positioned across from the back surface 109B of the workpiece 108. As it is advanced towards the second deposition station 104, the workpiece 108 enters the enclosure 110 from an entrance opening or slit 112A and exits the enclosure 110 from an exit opening 112B. In the first deposition unit, as shown in FIG. 4A, a first conductive material is deposited only on the back surface 109B of the workpiece to form a back conductive film 130 covering the back surface 109B of the workpiece 108 without leaving any exposed areas adjacent the edges of the workpiece. The deposition unit 102A may include a sputtering cathode with a target comprising the first conductive material. Deposition by the sputtering cathode 102A is carried out in a free-span mode. Due to the lack of a cooling system or device which is in direct contact with workpiece 108 in the first deposition station 102, the sputtering cathode 102A may be a low power sputtering cathode. Because of the low power and resulting low deposition rate of the sputtering cathode 102A, the back conductive film 130 may be kept thin in order not to lower the process throughput. Accordingly, the back conductive film 130 may have a thickness in the range of 20-100 nm. A higher thickness may take longer time due to the low power of the sputtering cathode 102A and reduce the throughput. A typical power range for the sputtering cathode 102A may be in the range of 1-10 KW for approximately 500 cm² area target. The target of the sputtering cathode 102A may be rectangular (such as 12 cm×40 cm rectangle) or cylindrical. The length of the target may be greater than the width of the workpiece so that the first conductive material can be deposited over the full back surface 109B of the workpiece 108. Since the deposition occurs within the enclosure 110, the excess first conductive material deposited beyond the edges of the back surface 109B is caught and held by the enclosure which may be cleaned at process intervals. The first conductive material is selected from a group that is resistive to reaction with Group VIA materials such as Se and S, so that when a precursor is later deposited over the top surface 109A and the workpiece 108 is passed through a roll-to-roll reactor to convert the precursor layer into a CIGS(S) type absorber film, the back surface 109B of the workpiece would be protected by the back conductive film 130 from the Se and/or S containing reactive atmospheres that are typically present in such reactors. In that respect the back conductive film 130 is a protective film that protects the back surface 109B from reaction with Group VIA materials.

Various roll-to-roll reactor designs for the formation of CIGS(S) type absorber layers on continuous workpieces are described in the following patent and patent applications of the assignee to this application, which are each expressly incorporated herein by reference in their entirety: U.S. Pat. No. 7,374,963, issued on May 20, 2008 entitled Technique and apparatus for depositing thin layers of semiconductors for solar cell fabrication; patent application Ser. No. 11/549,590 filed on Oct. 13, 2006, entitled Method and Apparatus for converting precursor layers into photovoltaic absorbers; application Ser. No. 11/938,679 filed on Nov. 12, 2007, entitled Reel-to-Reel reaction of precursor film to form solar cell absorber; and, application Ser. No. 12/027,169 filed on Feb. 6, 2008, entitled Reel-to-Reel Reaction of Precursor Film to Form Solar Cell Absorber.

Referring to FIG. 3A, the second deposition station 104 includes a support base 114 or drum to support the back surface 109B of the workpiece 108 while a second conductive material is deposited onto the front surface 109A by deposition units 104A-104E which are generally positioned across from the lower half of the drum 114. The back surface 109B of the workpiece 108 contacts a cylindrical surface 116 of the drum 114 as the workpiece is advanced towards the third deposition station 106. As in the previous embodiment, the deposition units 104A-104E are sputtering cathodes with targets comprising the second conductive material. The drum 114 of the second deposition station 104 is cooled and transfers the heat from the workpiece 108 during the deposition, thus it is a cooling device. Therefore, the sputtering cathodes 104A-104E of the second station may be high power sputtering cathodes to form conductive layers that are thicker than the conductive layers that may be formed in the first and third deposition stations 102 and 106. Since the heat generated during the deposition is removed by the drum 114, thicker conductive layers can be deposited in a short time by applying high power (such as 10-20 kW each) to the sputtering cathodes 104A-104E. The sputtering cathodes 104A-104E are used to deposit the second conductive material over the front surface 109A in an edge-excluding manner to form a first front conductive film 132 shown in FIG. 4B. The first front conductive film 132 generally covers a central area of the front surface 109A exposing an edge area 134 of the front surface 109A so that substantially no deposition occurs on the cylindrical surface 116 of the drum. The first front conductive film 132 may preferably have a thickness in the range of 200-4500 nm, which is thicker than the back conductive film 130, which may have a thickness in the range of 20-100 nm. As stated above, a typical power range for the sputtering cathodes 104A-104E may be in the range of 10-20 kW to keep manufacturing throughput high. In order to ensure that no unwanted deposition occurs on the cylindrical surface 116, the width of the mask opening (not shown) in front of the sputtering targets may be made less than the width of the workpiece. This ensures that any excess deposition towards the edges of the workpiece ends up on the edges of the mask. Although in this example all sputtering cathodes deposit the second conductive material, it is possible to deposit more than one material using the deposition sputtering cathodes 104A-104E. For example, the sputtering cathode 104A may deposit a Chromium (Cr) layer from a Cr target and the sputtering cathodes 104B-104E may all deposit molybdenum (Mo) on the central area of the front surface 109A from Mo targets. Or even, each sputtering cathode may deposit a different material. It should be noted that the central area of the front surface 109A on which the depositions are carried out within the second deposition station 104 constitute the area over which the solar cells are later fabricated. The edge area 134 of the front surface 109A is not used for solar cell fabrication. In that respect, the first front conductive film 132 is a portion of the contact layer shown in FIG. 1.

Referring to FIG. 3A, the third deposition station 106 includes an enclosure or shield 120 in which a deposition unit 106A is positioned across from the front surface 109A of the workpiece 108. The deposition unit 106A may be a sputtering cathode with a target comprising the third conductive material. The workpiece 108 enters the enclosure 110 from an entrance opening or slit 122A and exits the enclosure 110 from an exit opening 112B. In the third deposition unit, as shown in FIG. 4C, the third conductive material is deposited towards the front surface 109A of the workpiece 108 to form a second front conductive film 136 covering the first front conductive film 132 and the exposed edge areas 134 of the front surface 109A of the workpiece 108. As described above for the first deposition station 102, also due to the lack of a cooling system which is in direct contact with the workpiece in the third deposition station 106, the sputtering cathode 106A may be a low power sputtering cathode. Because of the low power and the resulting low deposition rate of the sputtering cathode 106A, the second front conductive film 136 may be kept thin in order not to lower the process throughput. Accordingly, the second front conductive film 136 may have a thickness in the range of 20-100 nm, which may be equal to the thickness of the back conductive film 130 but less than the thickness of the first front conductive film 132 which is deposited by the high power sputtering cathodes over the cooled drum. FIG. 4D shows a portion of the front surface of the workpiece which is fully coated with the second front conductive film 136. As in the first deposition station 102A, the width of the mask opening for the target may be greater than the width of the workpiece 108 so that the third conductive material can be deposited over the full front surface of the workpiece 108. Since the deposition occurs within the enclosure 120, the excess conductive material deposited beyond the edges of the front surface 109A is caught and held by the enclosure 120 which may be cleaned at process intervals.

As can be seen from FIG. 4C the portion of the second front conductive film 136 covering the exposed edge areas 134 of the front surface 109A of the workpiece 108 protects the exposed edge areas 134 from reactive atmospheres comprising Se and/or S if a precursor layer (not shown) is deposited only over the first front conductive film 132 and the whole workpiece is exposed to the reactive atmosphere at elevated temperatures in the range of 400-600° C. Alternately, a precursor layer may be deposited over the whole surface of the second front conductive film 136 including the edge areas 134. In this case the second front conductive film 136 provides good nucleation for the precursor layer and this way does not allow peeling and thus particle generation of the C1GS layer portion formed over the edge areas 134 during the reaction step. As described before, the first conductive material, the second conductive material, and the third conductive material may be selected from a group of materials resistant to reaction with Se and/or S. These materials include, but are not limited to, Mo, W, Ti, Ta, Cr, their alloys with other metals, their nitrides, Ru, Os, Ir, and the like. In one example, preferably the back conductive film 130 may include at least one of Ru and Mo, the first front conductive film 132 may include Mo, and the second front conductive film 136 may include Ru.

The process flow described above forms the first protected base structure 300 shown in FIG. 4C, wherein the flexible foil substrate is protected from reaction with Group VIA materials. Compared to the base 20 shown in FIG. 1, the first protected base structure 300 is unique to and tailored for roll-to-roll processing. In the first protected base structure 300 of FIG. 4C the flexible foil substrate is sandwiched between three conductive films, one over its back surface, two over its front surface where the solar cell absorber layer would be formed. Of the two front surface films, one is deposited over whole front surface of the substrate while the other one is only deposited over a central portion excluding a section along the two edges. It should be noted that each of the back surface film, the first front surface film, and the second front surface film may comprise one or more layers. For example, the back surface film may be a stack of Cr and Mo or it may actually have three or more layers. Similarly, the first and second front surface films may have multi-layer structures.

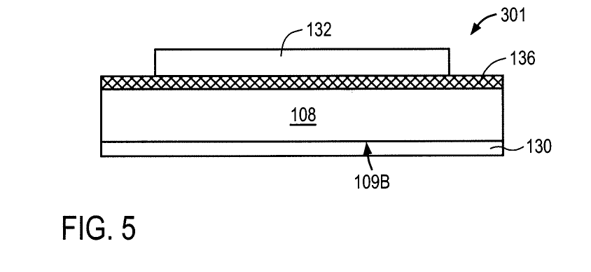

Alternatively, if the third deposition station 106 is placed between the first deposition station 102 and the second deposition station 104 as shown in a modified roll to roll deposition system 100A in FIG. 3B, a second protected base structure 301 shown in FIG. 5 may be formed. The second protected base structure 301 has many of the desirable features of the first protected base structure 300 of FIG. 4C. The difference is that the second front conductive film 136 in this case is under the first front conductive film 132. Referring to FIG. 5, in this embodiment, preferably the back conductive film 130 may include at least one of Ru and Mo, the first front conductive film 132 may include Mo, and the second front conductive film 136 may include Ru.

Another modified roll to roll system 100B shown in FIG. 3C, in addition to the second deposition station 104, includes more than one first and second deposition stations to add additional layers of back conductive and second front conductive films. The modified system 100B shown in FIG. 3C includes an additional first deposition station 102′ next to the first deposition station 102 and an additional third deposition station 106′ next to the third deposition station 106 to form a third protected base structure 301A shown in FIG. 8. The third protected base structure 300B differs from the first protected base structure 300 shown in FIG. 4C by an additional back conductive film 130′depositied on the back contact film 130 and an additional second front conductive film 136′ deposited on the second front conductive film 136. The materials of the conductive films 130′ and 136′include, but are not limited to, Mo, W, Ti, Ta, Cr, their alloys with other metals, their nitrides, Ru, Os, Ir, and the like. In one embodiment, an additional back conductive film 130′maybe Ru, the back contact film 130 may be Mo, the additional second front conductive film 136′ maybe Cu, the second front conductive film 136 may be Ru, and the first front conductive film 132 may be Mo.

Referring back to FIG. 3A, a number of auxiliary rollers 118 may be positioned at both sides of the drum 114 to monitor the speed of the workpiece, to adjust and monitor its tension, to direct the workpiece in and out of the enclosures 110 and 120 and to enable workpiece 108 to contact to at least a lower half of the cylindrical surface 116 as the workpiece is fed from the supply spool 111A and wrapped around the receiving spool 111B after the process.

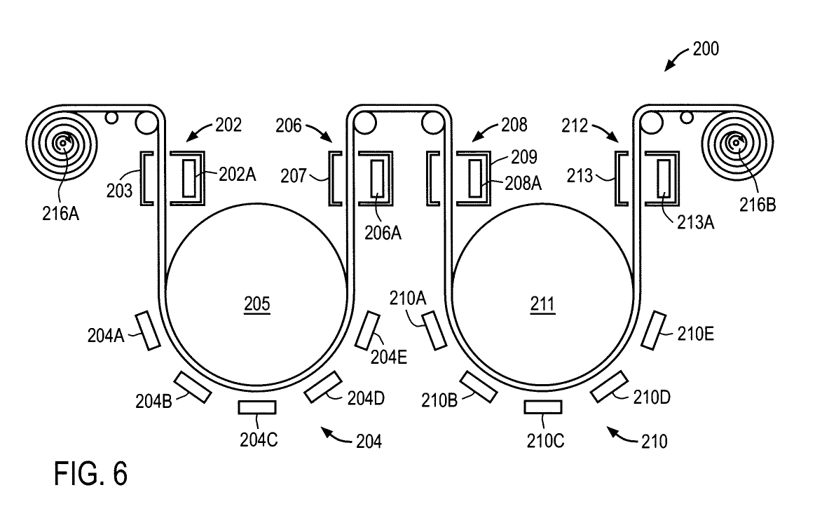

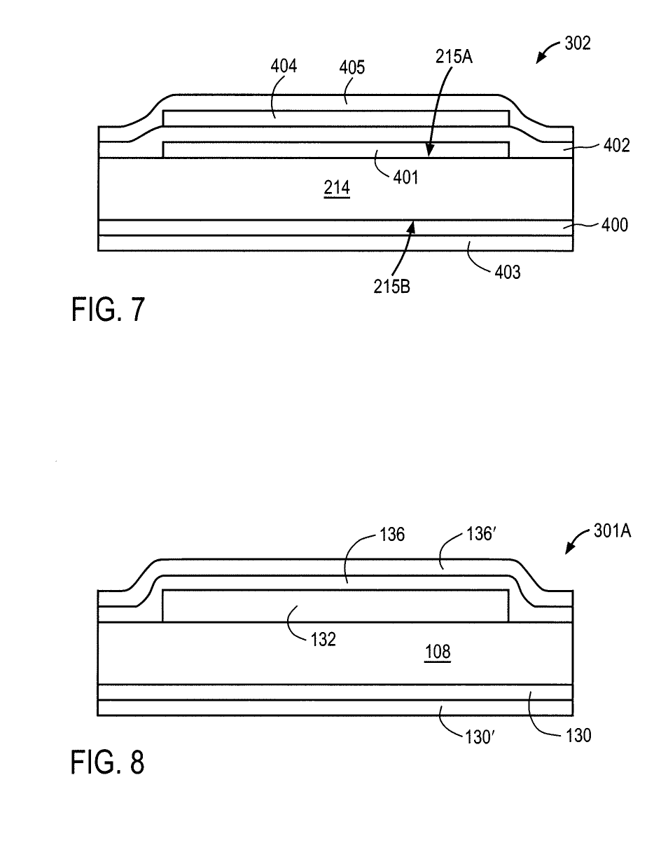

By increasing the number of deposition stations and/or the number of deposition units in each station, it is possible to sputter deposit multiple layers comprising one or more materials at high throughput. FIG. 6 shows a roll-to-roll system 200 having a first deposition station 202, a second deposition station 204, a third deposition station 206, a fourth deposition station 208, a fifth deposition station 210, and a sixth deposition station 212. As a workpiece 214 is advanced through the deposition stations 202, 204, 206, 208, 210 and 212, between a supply spool 216A and the receiving spool 216B, one or more conductive materials are deposited over a front surface 215A and a back surface 215B of the workpiece 214. Using the system 200, a third protected base structure 302 shown in FIG. 7 may be formed.

Referring to FIGS. 6 and 7, in one exemplary process sequence, in the deposition station 202, a first back conductive layer 400 is deposited over the back surface 215B using a deposition unit 202A while an enclosure 203 of the deposition unit prevents any contamination as described above. The first back conductive layer 400 fully covers the back surface 215B. In the deposition station 204, a first front conductive layer 401 is deposited over the front surface 215A of the workpiece using the sputtering cathodes 204A-204E. The first front conductive layer 401 is deposited over a central region of the front surface 215A so as to prevent any contamination on a surface of a drum 205.

In the deposition station 206, a second front conductive layer 402 is deposited over the first front conductive layer 401 and the exposed areas of the front surface 215A using a sputtering cathode 206A while an enclosure 207 of the deposition unit prevents any contamination . The second front conductive layer 402 is fully deposited over the front surface 215A. In the deposition station 208, a second back conductive layer 403 is deposited over the first back conductive layer 400 using a sputtering cathode 208A while an enclosure 209 of the deposition unit prevents any contamination. The second back conductive layer 403 fully covers the first back conductive layer 400. In the deposition station 210, a third front conductive layer 404 may be deposited over the second front conductive layer 402 using sputtering cathodes 210A-210E and a fourth front conductive layer 405 may be deposited over the third front conductive layer 404 using sputtering cathode 212A in deposition station 212 while an enclosure 213 of the deposition station 212 prevents any contamination. The third front conductive layer 404 is deposited in edge excluding manner on the second front conductive layer 402 so as to prevent any contamination on a surface of a drum 211. In the roll to roll system 200, it will be appreciated that by activating or deactivating a certain number of deposition stations by a control system, the protected base structures shown in FIGS. 4C, 5 and 8 and other possible structures can be advantageously obtained. For example, during the deposition process if the sputtering cathodes 210A-210E are not (switched off), a protected base structure similar to the one shown in FIG. 8 can be easily obtained.

As can be seen from the above description, the embodiments described herein provide solutions to issues that are especially important for roll-to-roll manufacturing of CIGS-type solar cells using metallic foils as substrate. In roll-to-roll manufacturing of CIGS-type solar cells it is important to process a base on which a solar cell can be fabricated, wherein the base: i) can be fabricated at high throughput, ii) is resistive against reaction with Group VIA materials, and iii) provides a contact layer with a minimum thickness of about 200 nm on the metallic foil portion, over which the solar cells are fabricated, so that no diffusion of impurities (such as Fe) takes place from the substrate through the contact layer into the CIGS absorber. Such impurity diffusion lowers the efficiency of solar cells.

The embodiments employ methods and equipment that integrate a free-span sputtering process where the substrate travels in front of sputtering targets without touching a cooling surface so that deposition of a material over a full surface of the substrate may be achieved; with a cooled-sputtering process where sputtering is performed only on a central region of the substrate while the substrate is wrapped around a cooled drum. In free-span sputtering from a series of targets (mounted on a series of cathodes) onto the workpiece, the temperature of a portion of the workpiece gets higher and higher as the portion travels in front of more and more cathodes. This is because heat is pumped into the workpiece from each cathode and it is not removed effectively in the vacuum environment of the sputtering system. As a result, in a free-span system, the properties of the deposited layers change through the thickness of the materials that are deposited since the deposition temperature changes. Also, high power densities that are needed for high process throughputs for depositing thick layers cause excessive substrate heating, pushing substrate temperatures to over 500 C or more. Therefore, power densities have to be limited in such tools which make them very long and low throughput for depositing thick layers. Sputtering on substrates cooled by a drum, on the other hand, can be carried out at high power densities at high throughput, but they don't yield full surface coverage of the deposit. The embodiments satisfy the requirements for a protected base for CIGS solar cell manufacturing by; i) depositing back and front surface protective layers that are needed to completely envelope the substrate to protect it from reaction with Group VIA materials using free-span sputtering since these layers can be thin and thus can be processed at high throughput without excessively heating the substrate, ii) depositing bulk of the contact layer over the central region of the substrate at high rate to provide a thick diffusion barrier film at high manufacturing throughput.

The protected base structures formed on flexible metallic substrate structures may be used in fabrication of CIGS type absorber layers over their front surfaces in a roll-to-roll manner. CIGS type absorber layer growth may be achieved by co-deposition (co-sputtering or co-evaporation) techniques or by two-stage approaches where a precursor layer is first deposited over the front surface of the base and then reacted with Se and/or S to form the compound. Solar cells may then be fabricated using established methods comprising deposition of transparent layers over the CIGS type absorber films. Finger patterns may also be deposited over the transparent layers. The roll to roll deposition systems described above may have a control system to control the deposition stations and the operation of the sputtering cathodes; therefore, various multiple films can be selectively deposited on both surfaces of a substrate to form desired film stacks.

Although the present inventions are described with respect to certain preferred embodiments, modifications thereto will be apparent to those skilled in the art.

We claim:

1. A method of sputter depositing a plurality of films on a back surface and a front surface of a continuous substrate that is advanced in a process direction through a deposition chamber, comprising:
depositing a first film onto a back surface portion of the back surface of the continuous substrate, the back surface portion including an entire width of the back surface, wherein the depositing of the first film uses at least a first sputtering target disposed across from the back surface portion of the continuous substrate as the continuous substrate is advanced in the process direction past the first sputtering target; and
depositing a second film over a front surface portion of the front surface of the continuous substrate, the second film being shaped as a central region that is not disposed over a pair of edge regions of the front surface portion along the width of the front surface, wherein the depositing of the second film uses at least one second sputtering target disposed across from the front surface portion of the continuous substrate as the continuous substrate is advanced in the process direction past the at least one second sputtering target, and wherein the depositing of the second film occurs while a corresponding back surface portion is supported and cooled by a cooling surface of a cooling mechanism as the continuous substrate is moved along the process direction past the at least one second sputtering target,

2. The method of claim 1, wherein step of depositing deposits the second film on the front surface portion, and further including:
depositing a third film onto the second film and onto the pair of exposed front surface portions formed by the pair of edge regions, thereby depositing across an entire width of the front surface portion, wherein the depositing uses at least a third sputtering target disposed across from the front surface portion of the continuous substrate, and wherein the depositing of the third film occurs while the continuous substrate is advanced in the process direction past the third sputtering target, after being removed from contact with the cooling surface of the cooling mechanism.

3. The method of claim 2 wherein the first film is at least one of Mo and Ru, the second film is Mo, and the third film is Ru.

4. The method of claim 2 further including depositing a fourth film over the third film using at least a fourth sputtering target disposed across from the front surface portion of the continuous substrate, and wherein the depositing of the fourth film occurs while the continuous substrate is advanced in the process direction past the fourth sputtering target, and while still being removed from contact with the cooling surface of the cooling mechanism.

5. The method of claim 4 wherein the first film is at least one of Mo and Ru, the second film is Mo, the third film is Ru, and the fourth film is Cu.

6. The method of claim 4 wherein the at least one second sputtering target is a plurality of second sputtering targets, and wherein each of the plurality of second sputtering targets deposit some of the second film and are disposed across from the front surface portion of the continuous substrate as the continuous substrate is advanced in the process direction.

7. The method of claim 1, wherein the cooling mechanism is a drum that rotates about an axis that is transverse to the process direction, and wherein the cooling surface is a peripheral surface of the drum.

8. The method of claim 5, wherein the drum is cooled by a fluid, thereby providing for transfer of heat from the continuous substrate to the drum while the depositing of the second film using the second sputtering target occurs.

9. The method of claim 1, wherein each of the first film, the second film and the third film comprises at least one of Mo, Cr, W, Ti, Ta, Ru, Os and Ir.

10. The method of claim 1, wherein the continuous substrate is one of stainless steel and aluminum.

11. The method of claim 1, wherein the at least one second sputtering target is a plurality of second sputtering targets, and wherein each of the plurality of second sputtering targets deposit some of the second film and are disposed across from the front surface portion of the continuous substrate as the continuous substrate is advanced in the process direction.

12. The method of claim 1 wherein the first film is at least one of Mo and Ru and the second film is Mo.

13. The method of claim 1, further including:
depositing a third film across an entire width of the front surface portion prior to the step of depositing the second film, wherein the depositing the third film uses at least a third sputtering target disposed across from the front surface portion of the continuous substrate, and wherein the depositing of the third film occurs while the continuous substrate is advanced in the process direction past the third sputtering target; and
wherein the depositing of the second film deposits the second film on the third film.

14. The method of claim 13, wherein the first film is at least one of Mo and Ru, the second film is Mo, and the third film is Ru.

15. The method of claim 1, wherein the at least one second sputtering target is a plurality of second sputtering targets, and wherein a first group of the plurality of second sputtering targets deposit a first layer of the second film and are disposed across from the front surface portion of the continuous substrate as the continuous substrate is advanced in the process direction, and wherein a second group of the plurality of second sputtering targets deposit second layer of the second film and are disposed across from the front surface portion of the continuous substrate as the continuous substrate is advanced in the process direction and wherein the material of the first layer is different than the material of the second layer.

16. A system to deposit a plurality of films on a back surface and a front surface of a continuous substrate that is advanced in a process direction, comprising:
a first deposition station including at least a first sputtering target disposed across from a back surface portion of the continuous substrate to continuously deposit a first film onto the back surface portion to form a first film on the back surface; and
a second deposition station, including at least one second sputtering target and a cooling mechanism having a cooling surface to deposit a second film over a front surface portion of the front surface of the continuous substrate, the second film being shaped as a central region that is not disposed over a pair of edge regions of the front surface portion along the width of the front surface, wherein the at least one second sputtering target is disposed across from a front surface portion of the continuous substrate as the continuous substrate is advanced in the process direction past the at least one second sputtering target, and wherein the depositing of the second film occurs while a corresponding back surface portion is supported and cooled by the cooling surface of the cooling mechanism as the continuous substrate is moved along the process direction past the at least one second sputtering target.

17. The system of claim 16 further comprising a third deposition station disposed adjacent the second deposition station for depositing a third film over the front surface portion and across an entire width thereof, and not depositing the third film onto the cooling mechanism, wherein the third deposition stations includes at least a third sputtering target disposed across from the front surface portion of the continuous substrate, and wherein the depositing of the third film occurs while the continuous substrate is advanced in the process direction past the third sputtering target.

18. The system of claim 17 further comprising a supply roll from which the continuous substrate is advanced in the process direction towards the first deposition station, and a receiving roll that the continuous substrate received from the third deposition station is wrapped around.

19. The system of claim 17, wherein the cooling surface is a peripheral surface of a drum that rotates about an axis that is transverse to the process direction, wherein as the continuous substrate is moved along the process direction, some of a portion of the peripheral surface supports the section of the continuous substrate.

20. The system of claim 19, wherein the cooling mechanism is a drum that rotates about an axis that is transverse to the process direction, and wherein the cooling surface is a peripheral surface of the drum.

21. The system of claim 20, wherein the drum is cooled by a fluid, thereby providing for transfer of heat from the continuous substrate to the drum while the depositing of the second film using the second sputtering target occurs.

22. The system of claim 17, wherein the at least one second sputtering target is a plurality of second sputtering targets, and wherein each of the plurality of second sputtering targets deposit some of the second film and are disposed across from the front surface portion of the continuous substrate as the continuous substrate is advanced in the process direction.

23. The system of claim 17 further comprising a fourth deposition station disposed adjacent the second deposition station for depositing a fourth film onto the third film across an entire width theof, and not depositing the fourth film onto the cooling mechanism, wherein the fourth deposition stations includes at least a fourth sputtering target disposed across from the front surface portion of the continuous substrate, and wherein the depositing of the fourth film occurs while the continuous substrate is advanced in the process direction past the fourth sputtering target and while still being removed from contact with the cooling surface of the cooling mechanism of the second deposition station.

24. The system of claim 23, wherein the at least one second sputtering target is a plurality of second sputtering targets, and wherein each of the plurality of second sputtering targets deposit some of the second film and are disposed across from the front surface portion of the continuous substrate as the continuous substrate is advanced in the process direction.

25. The system of claim 16, wherein the at least one second sputtering target is a plurality of second sputtering targets, and wherein each of the plurality of second sputtering targets deposit some of the second film and are disposed across from the front surface portion of the continuous substrate as the continuous substrate is advanced in the process direction.
